(19) United States
(12) Patent Application Publication
(10) Pub. No.: US 2026/0238201 A1
(43) Pub. Date: Aug. 13, 2026

(54) CLOCK DUTY CYCLE MONITORING AND ADJUSTMENT

(71) Applicant: QUALCOMM Incorporated, San Diego, CA (US)

(72) Inventors: Farrukh AQUIL, San Diego, CA (US); Boris Dimitrov ANDREEV, San Diego, CA (US); Patrick ISAKANIAN, El Dorado Hills, CA (US); Yong XU, San Diego, CA (US); Vishal MISHRA, San Diego, CA (US)

(21) Appl. No.: 19/048,525

(22) Filed: Feb. 7, 2025

(51) Int. Cl. H03K 5/156; G11C 11/4076

(52) U.S. Cl. CPC H03K 5/1565; G11C 11/4076

(57) ABSTRACT

Certain aspects of the disclosure relate to a memory device and a clock duty cycle adjuster (DCA) that is located after a clock divider to ensure that the duty cycle feedback can adjust the clock post-divider without affecting the divider's input clock. In some aspects, a duty cycle monitor (DCM) can be placed at the input clock to the divider to enable a host using a memory device to use its own DCA based on feedback from the DCM.

### TECHNICAL FIELD

The present disclosure relates generally to integrated circuit technology and more particularly to techniques for clock duty cycle monitoring and adjustment.

### BACKGROUND

Semiconductor memories are used in many electronic systems to store data that may be retrieved at a later time. An example of semiconductor memory is low power double data rate (LPDDR) memory. In LPDDR memory, the clock signal plays a critical role in synchronizing all memory operations, ensuring accurate communication between the memory controller and the LPDDR memory module. Deviations in the timing of clock signal, such as duty cycle distortion can lead to errors, reduced performance, and data corruption. Semiconductor memories can incorporate duty cycle monitor (DCM) and duty cycle adjuster (DCA) circuits to correct distortions in the clock signals. When properly adjusted, DCA circuits enhance reliability, reduce timing errors, and enable higher data rates by ensuring optimal synchronization across commands, addresses, and data transfers.

### SUMMARY

The following presents a summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a form as a prelude to the more detailed description that is presented later.

Certain aspects of the disclosure relate to a clock duty cycle adjuster (DCA) that is relocated after a clock divider to ensure that the duty cycle feedback can adjust the clock post-divider without affecting the divider's input clock. In some aspects, a duty cycle monitor (DCM) can be placed at the input clock to the divider to enable a host using a memory device to use its own DCA based on feedback from the DCM.

One aspect of the disclosure provides a memory apparatus. The memory apparatus includes a clock divider configured to divide an input clock signal into an internal clock signal with a reduced frequency, a clock tree configured to distribute the internal clock signal to one or more internal components of the memory apparatus, and a first duty cycle adjuster (DCA) connected to the clock tree. The first DCA is configured to adjust a clock timing of the internal clock signal based on a duty cycle feedback pertaining to the internal clock signal.

One aspect of the disclosure provides a method for controlling clock timing of a memory apparatus. The method includes a process of dividing an input clock signal into an internal clock signal with a reduced frequency. The method includes a process of distributing the internal clock signal to one or more internal components of the memory apparatus. The method further includes a process of adjusting a clock timing of the internal clock signal based on a duty cycle feedback pertaining to the internal clock signal.

One aspect of the disclosure provides a memory apparatus. The memory apparatus includes means for dividing an input clock signal into an internal clock signal with a reduced frequency, means for distributing the internal clock signal to one or more internal components of the memory apparatus, means for adjusting a clock timing of the internal clock signal based on a duty cycle feedback pertaining to the internal clock signal.

### BRIEF DESCRIPTION OF THE DRAWINGS

FIG. 1 illustrates an apparatus that can be implemented as an integrated circuit (IC) device including multiple components according to some aspects of the disclosure.

FIG. 2 illustrates certain aspects of a system-on chip (SoC) and memory according to some aspects of the disclosure.

FIG. 3 illustrates an exemplary duty cycle monitoring (DCM) apparatus according to some aspects of the disclosure.

FIG. 4 illustrates an exemplary duty cycle monitoring process according to some aspects of the disclosure.

FIG. 5 illustrates an exemplary duty cycle adjustment apparatus according to some aspects of the disclosure.

FIG. 6 illustrates an exemplary duty cycle adjustment process according to some aspects of the disclosure.

FIG. 7 illustrates an exemplary adjustment sweeping process using a duty cycle adjustment apparatus according to some aspects of the disclosure.

FIG. 8 is a flow chart illustrating a method for adjusting the clock duty cycle of a memory apparatus according to some aspects of the disclosure.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well-known structures and components are shown in block diagram form in order to avoid obscuring such concepts.

Several aspects of the disclosure will now be presented with reference to various apparatus and methods. These apparatus and methods will be described in the following detailed description and illustrated in the accompanying drawings by various blocks, modules, components, circuits, steps, processes, algorithms, etc. (collectively referred to as “elements”). These elements may be implemented using electronic hardware, computer software, firmware, or any combination thereof. Whether such elements are implemented as hardware or software depends upon the particular application and design constraints imposed on the overall system.

In a computing apparatus, a common duty cycle adjuster (DCA) can be positioned before a clock divider for a memory device. The DCA can adjust the clock duty cycle based on duty cycle feedback along a clock tree. However, this adjustment can introduce pre-distortion to the input clock of the divider, further impacting the desired duty cycle and degrading performance. The present disclosure provides a novel approach to clock duty cycle adjustment and monitoring. In some aspects, a DCA can be relocated after the clock divider to ensure that the duty cycle feedback adjusts the clock post-divider without affecting the divider's input clock. Additionally, another duty cycle monitor (DCM) can be placed at the input clock to the divider to enable a host using the memory device to use its own DCA based on feedback from the DCM.

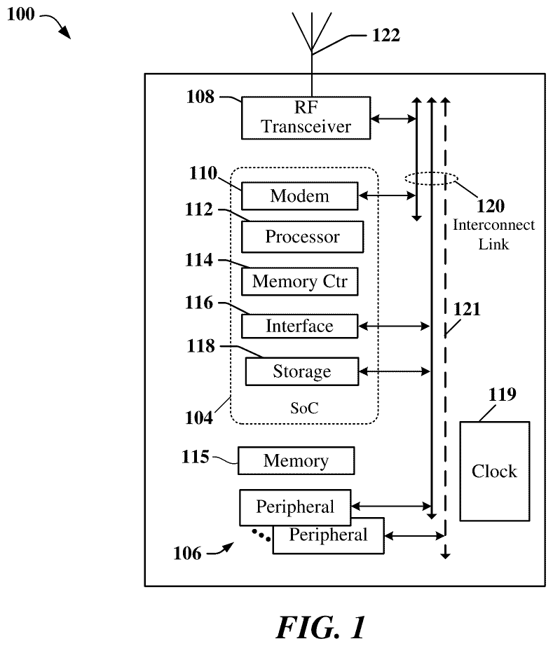

FIG. 1 illustrates an example of an apparatus 100 that can be implemented as an integrated circuit (IC) device including multiple components including, for example, a system-on-chip (SoC) and memory. In some examples, the apparatus 100 can be enclosed within a portable or a wearable device, such as a smartwatch or a mobile device (e.g., smartphone, mobile phone, notebook, tablet, etc.). In some aspects, the apparatus 100 includes various circuitry to perform different functions. In various examples, the circuitry can be implemented using one or more dies (e.g., chiplets) arranged in a configuration that can be adapted for use in mobile computing, embedded computing, edge computing, etc. In some aspects, the apparatus 100 may be configured to support multiple communication technologies, modes, and/or protocols. In some aspects, the apparatus 100 can include a SoC 104, one or more peripheral devices 106, and one or more transceivers 108 that cooperate to enable the apparatus to communicate through one or more antennas 122 with a radio access network (RAN), a core access network, the Internet, and/or another network. In some examples, the apparatus 100 can communicate with another device using a peer-to-peer (P2P) or device-to-device connection (e.g., Bluetooth, Wi-Fi, vehicle-to-vehicle (V2V) connection, or vehicle-to-everything (V2X) connection), or a mesh network.

In some aspects, the SoC 104 may include various circuitry, for example, one or more processors 112, one or more modems 110, a memory controller 114, a communication interface circuit 116 (e.g., a bus interface), and/or other logic circuits or functions. The SoC may include on-board memory and/or external memory 115. In some examples, the memories can include low power double data rate (LPDDR) memory. The SoC can be controlled by an operating system that provides an application programming interface (API) layer that enables the one or more processors 112 to execute software modules or instructions residing in the one or more memories and/or other processor-readable storage 118 provided on the SoC. The software modules may include instructions and data stored in the one or more memories 115 and/or processor-readable storage 118. The SoC 104 may access one or more memories (e.g., memory 115), the processor-readable storage 118, and/or storage external to the apparatus 100. The one or more memories and the processor-readable storage 118 may include read-only memory (ROM), random-access memory (RAM), electrically erasable programmable ROM (EEPROM), flash memory, or any memory device that can be used in processing systems and computing platforms. The apparatus may include, implement, or have access to a local database or other parameter storage (e.g., tables, database, etc.) that can maintain operational parameters and other information used to configure and operate the apparatus 100 and/or the SoC 104. The local database may be implemented using registers, a database module, flash memory, magnetic media, EEPROM, soft or hard disk, or the like. The SoC 104 may also be coupled to external devices such as the antenna 122, a display, operator controls, switches or buttons, among other components.

In some aspects, the apparatus 100 can include clock circuitry 119 (e.g., including a clock source, a clock divider, a duty cycle adjuster (DCA), a duty cycle monitor (DCM), a clock distribution network, etc.) configured to generate one or more clock signals for timing operations of the apparatus. In one example, the clock source may be implemented with a phase-locked loop (PLL) or another type of clock generator. In some aspects, various components of the clock circuitry 119 can be located in the SoC and/or memory 115.

The apparatus 100 can provide one or more interconnect links (e.g., interconnect link 120) that enables communication between different components (e.g., SoC 104, peripheral 106, and/or 108 RF transceiver) that can be implemented in one or more dies (e.g., chiplets). In one example, the SoC 104 may include communication interface circuits 116 coupled to the interconnect. Each of the interface circuits 116 may include a combination of circuits, counters, timers, control logic and other configurable circuits or modules. In one example, certain interconnect interface circuits 116 may be configured to operate in accordance with standards-defined communication specifications or protocols. The apparatus 100 may include or control a power management function that configures and manages the operation of the apparatus 100.

In some aspects, the apparatus 100 may be included in mobile phones, tablet computers, palmtop computers, portable digital assistants (PDAs), portable game consoles, tablets, smartwatches, and other portable electronic devices. The various components of the apparatus 100 may communicate with each other via one or more intra-chip communication interconnects. The apparatus 100 can be packaged in an integrated circuit (IC) package, which may be referred to as a “semiconductor package” or “chip package.” The IC package typically includes a package substrate and one or more IC chips, dies, chiplets, or other electronic modules mounted to the package substrate to provide electrical connectivity to the IC chips, dies, or chiplets. For example, an IC chip in an IC package may be configured as an SoC. The IC chips are electrically coupled to other IC chips and/or to other components in the IC package through electrical coupling to metal lines in the package substrate. The IC chips can also be electrically coupled to other circuits outside the IC package through electrical connections of external metal interconnects (e.g., solder bumps) of the IC package.

Process technology employed to manufacture semiconductor devices, including IC devices, is continually improving. Process technology includes the manufacturing methods used to make IC devices and defines transistor size, operating voltages, and switching speeds. Features that are constituent elements of circuits in an IC device may be referred as technology nodes and/or process nodes. The terms technology node, process node, and process technology may be used to characterize a specific semiconductor manufacturing process and corresponding design rules. Faster and more power-efficient technology nodes are being continuously developed through the use of smaller feature size to produce smaller transistors that enable the manufacture of higher-density ICs. Design rules for newer process technology that use low-voltage transistors may preclude the use of higher voltage transistors supported by previous process technology generations. The unavailability of certain higher-voltage transistors may present an impediment to circuit designers for IC devices that include multiple voltage domains.

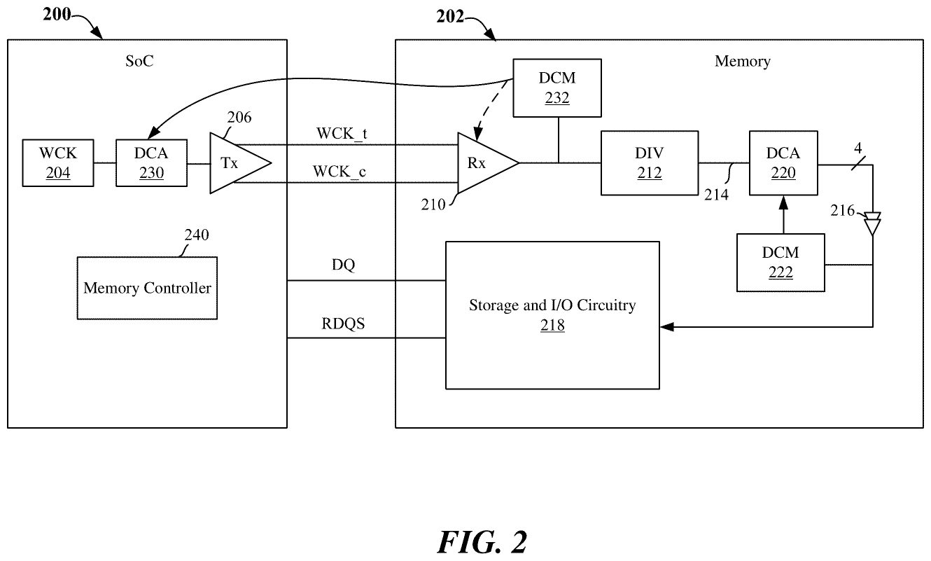

FIG. 2 is a block diagram illustrating certain aspects of an apparatus including an SoC 200 and a memory 202 according to some aspects. In one example, the SoC 200 may be the SoC 104 of FIG. 1 or any other SoC, the memory 202 can be memory 115 (e.g., LPDDR memory) of FIG. 1. In some aspects, the SoC 200 may include a variety of processing engines, such as central processing units (CPUs) with multiple cores, graphical processing units (GPUs), digital signal processors (DSPs), neural processing units (NPUs), wireless transceiver units (also referred to as modems), peripherals, display and imaging interfaces, etc. Each of these subsystems and other functional elements can be implemented as an individual chiplet, or as a combination of chiplets. The chiplets included in the SoC 200 can be proprietary or may be acquired from a variety of sources.

The SoC 200 can provide a clock source (e.g., WCK 204) and an output buffer 206 configured to output differential write clock signals WCK_t and WCK_c. WCK_t is the positive signal, and WCK_c is the complement (negative) signal. The clock signals have a predetermined duty cycle for optimal operation of the memory 202. A clock signal duty cycle can be expressed as a percentage (e.g., 50%) or a fraction of a clock period (i.e., clock cycle) in which the clock signal is in a high phase (i.e., one). Precise control of the duty cycle can reduce timing errors and ensure high-speed data integrity.

The memory 202 can use an input clock buffer (e.g., Rx 210) to receive the clock signals WCK_t and WCK_c. The input clock buffer 210 provides buffered WCK_t and WCK_c clocks to a clock divider (e.g., DIV 212). The clock divider 212 can generate multiple clock signals 214 that have a clock frequency less than the frequency of the WCK_t and WCK_c clock signals. The multiple clock signals may have a phase relationship relative to one another. For example, the clock signals can have a phase relationship of 90 degrees relative to one another (e.g., 0 degrees, 90 degrees, 180 degrees, 270 degrees), and have a clock frequency that is a fraction (e.g., one-half) of the frequency of the WCK_t and WCK_c clocks. However, the present disclosure is not intended to be limited to this particular number of clocks, phase relationship, and/or clock frequency.

The clock signals can be distributed over a clock tree 216 to other circuitry or components that may be operated according to the clock signals. The clock tree is a hierarchical network within memory 202 to distribute the clock signals from a single source (e.g., DIV 212) to multiple destinations. In some aspects, the memory 202 has core storage and input/output circuitry 218 that uses the clock signals for timing the operation to send and receive data (DQ) to/from the SoC 200. For read operations, the SoC can receive the read strobe (RDQS) and read data (DQ) from the memory based on the data clocks.

In some aspects, the memory 202 can provide a DCA 220 after (downstream) the clock divider 212. The memory 202 can use a duty cycle monitor (DCM) 222 to monitor the timing (e.g., duty cycle) of the clock signals on the clock tree 216 after (downstream) the clock divider 212 and DCA 220. Based on DCM feedback (e.g., duty cycle feedback), the DCA 220 can adjust the clock signals after the clock divider 212 to avoid causing distortion to the clock input of the clock divider 212. For example, the DCA 220 can adjust the timing (e.g., duty cycle) of the clock signals without affecting the clock inputs of the clock divider 212. That is, the DCA 220 can adjust the clock duty cycle independent of the clock input of the clock divider 212.

In some aspects, the SoC can further include a DCA 230 (a second DCA) configured to adjust the timing (e.g., duty cycle) of the clock signals before the clock divider 212. The memory 202 can include a DCM 232 to monitor the clock input of the clock divider 212. The DCA 230 at the SoC can adjust the timing (e.g., duty cycle) of the clock signals based on the feedback from the DCM 232 at the input of the clock divider 212. In some aspects, the SoC can use DCA 230 to sweep the duty cycle and read the feedback from the DCM 232. Sweeping the duty cycle can determine the duty cycle range within which the clock divider 212 will operate correctly and the optimal duty cycle. In some aspects, the DCA can be implemented as part of the input clock buffer 210 to correct the duty cycle at the input of clock divider 212. By using above described clock DCA-DCM schemes, the clock divider 212 input clock signal has improved duty cycle and the clock divider has improved bandwidth to meet higher frequency demands. In some aspects, a memory controller 240 included in the SoC or an external memory controller (e.g., memory controller 114 of FIG. 1) can control the operations of the DCM as DCA described above.

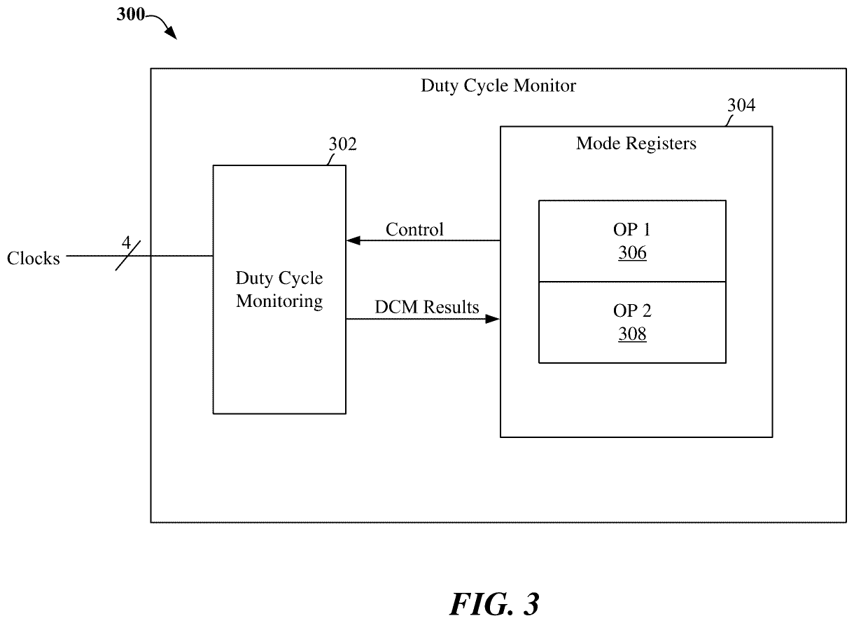

FIG. 3 is a block diagram of an exemplary duty cycle monitoring (DCM) apparatus 300 according to some aspects of the disclosure. The DCM 300 can be used to implement any of the DCMs 222 and 232 of FIG. 2. The DCM apparatus 300 can be implemented in software and/or hardware in various designs. The DCM apparatus 300 can monitor the clock timing of a clock tree. For example, the DCM apparatus 300 may be configured to monitor a duty cycle of one or more of the clock signals of the memory 202 of FIG. 2. In one example, the memory 202 can be a LPDDR memory. The DCM apparatus 300 can include duty cycle monitoring circuitry 302 and one or more mode registers 304. The duty cycle monitoring circuitry 302 can monitor one or more clock signals and provide information indicative of timing (e.g., duty cycle, edge timings, etc.) of the clock signals. The timing and control information may be stored in the mode registers 304, where the results may be accessed and provided externally, for example, in response to a mode register read command from a processor or host (e.g., the SoC 200 of FIG. 2).

The mode registers 304 may store information that controls the operation of the duty cycle monitoring circuitry 302. For example, the control information can control when the duty cycle monitoring circuitry 302 starts and stops monitoring the clock signals. The duty cycle monitoring circuitry 302 can store the monitoring results at the mode registers 304. In some aspects, information may be stored at the mode registers 304 as opcodes. For example, the information for controlling the starting and stopping of the duty cycle monitoring circuitry 302 can be stored as a first opcode 306, and the monitoring results provided by the duty cycle monitoring circuitry 302 can be stored as a second opcode 308. The number of opcodes used may be different for different implementations of the disclosure, and consequently, the scope of the disclosure is not limited to the particular example shown in FIG. 3.

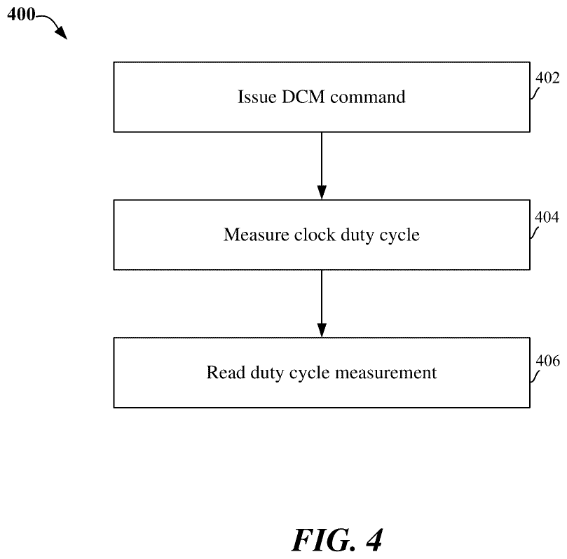

FIG. 4 illustrates an exemplary clock duty cycle monitoring process 400 according to some aspects of the disclosure. For example, an SoC (e.g., SoC 200 of FIG. 2) can use this clock duty cycle monitoring process to monitor clock tree timings in a memory device (e.g., the memory 202 of FIG. 2, LPDDR memory, or any memory devices).

At step 402, the SoC can issue a DCM command to a memory (e.g., memory 202 of FIG. 2) to start clock duty cycle monitoring. In one aspect, a memory controller of the SoC (e.g., memory controller 114 of FIG. 1) can issue the command. In one example, the DCM command can be a mode register write command (MGWR) that stores an opcode (e.g., opcode 306) at the mode registers 304. The MGWR causes the memory to measure clock tree duty cycle using a DCM (e.g., DCM 222 or 232 of FIG. 2). In response to the command, at step 404, the DCM can measure and capture the clock timings (e.g., duty cycle, edge timings) of the clock tree. For example, the DCM apparatus can use the duty cycle monitoring circuitry 302 of FIG. 3 to monitor the clock duty cycle and store the result as an opcode (e.g., opcode 308 of FIG. 3) in a mode register. At step 406, the SoC can read out the DCM results from the mode register by issuing a mode register read command (MGRD) to the memory. In response to the MGRD, the memory (e.g., DCM apparatus 300 of FIG. 3) can send the results to the SoC or a memory controller (e.g., memory controller 114). In some aspects, the above described duty cycle monitoring process 400 can be performed using the DCM 222 and DCM 232, respectively as separate processes, enabling the SoC and/or memory to monitor the clock tree at different locations, for example, before and after a clock divider.

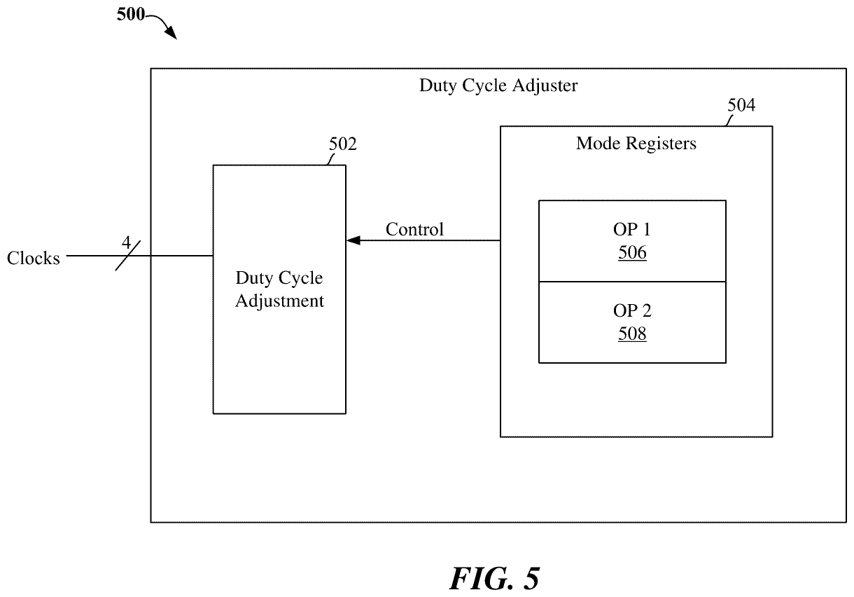

FIG. 5 illustrates an example of a duty cycle adjustment (DCA) apparatus 500 according to some aspects of the disclosure. The DCA 500 apparatus can be a register-controlled DCA that enables an SoC (e.g., SoC 200 of FIG. 2) to adjust the clock tree duty cycle of a memory (e.g., memory 202 of FIG. 2). For example, the DCA apparatus 500 can adjust the duty cycle of clock signals in FIGS. 1 and 2. The DCA apparatus 500 can be implemented as software and/or hardware in various designs.

In one aspect, the DCA apparatus 500 can be implemented after a clock divider (e.g., at the clock outputs of DIV 212 of FIG. 2) to adjust the clock duty cycle after (downstream) the outputs of the clock divider. In one aspect, the DCA apparatus 500 can be implemented at the SoC or included in a clock buffer (e.g., clock buffer 210 of FIG. 2). In this case, the DCA apparatus can adjust the clock duty cycle before or at the inputs of the clock divider. The DCA apparatus 500 has duty cycle adjustment circuitry 502 and one or more mode registers 504. The duty cycle adjustment circuitry 502 is configured to adjust the clock duty cycle according to opcodes (e.g., opcodes 506, 508) stored at the mode registers 504. If the duty cycle deviates from the optimal duty cycle (e.g., 50%), the SoC or memory controller can program specific settings into the mode registers to adjust the clock. For example, the SoC or memory controller can adjust the duty cycle of the clock tree by storing information in the mode registers 504, for example, as opcodes. In some aspects, the DCA apparatus can adjust the high phase and/or low phase of a clock in a range of steps according to the opcodes. In one example, the duty cycle adjustment circuitry 502 can increase or decrease the high duty cycle of the clock tree. In one example, the duty cycle adjustment circuitry 502 can increase or decrease the low duty cycle of the clock tree. In some aspects, the opcodes can provide multiple step sizes to facilitate efficient clock duty cycle adjustment. For example, the opcodes can indicate the duty cycle adjustment step (increase or decrease) or size.

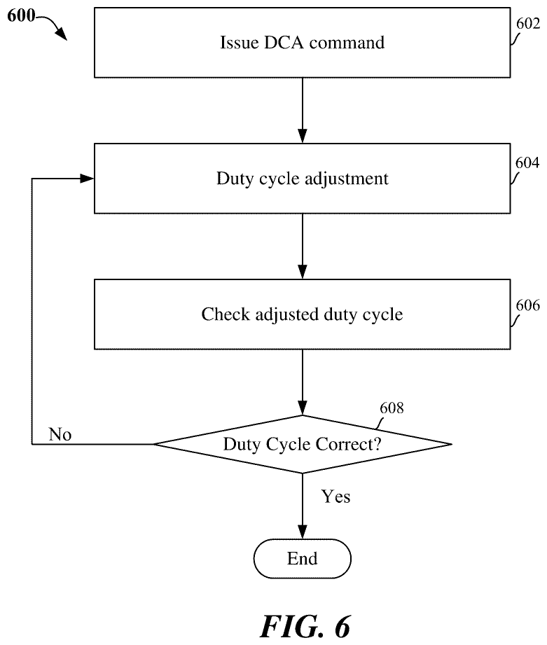

FIG. 6 illustrates an exemplary duty cycle adjustment (DCA) process 600 according to some aspects of the disclosure. For example, an SoC (e.g., SoC 200 of FIG. 2) or memory controller can use the DCA process to monitor clock timings in a memory (e.g., the memory 202 of FIG. 2, LPDDR memory, or any memory devices). The SoC/memory can use the DCA process to monitor clock timings before and after a clock divider (e.g., clock divider 212 of FIG. 2).

At 602, the SoC/memory can send a DCA command to a DCA apparatus (e.g., DCA 220 or 230 of FIG. 2) to adjust the duty cycle of a clock signal. For example, the SoC/memory can program specific settings into the mode registers (mode registers 504 of FIG. 5) of the DCA apparatus to adjust the clock signal when the duty cycle deviates from the optimal duty cycle (e.g., 50%).

At 604, the DCA apparatus can adjust the duty cycle of the clock signal based on a DCA command. For example, the DCA command can cause the DCA apparatus to increase or decrease the duty cycle of the clock tree by a predetermined step or amount. The DCA apparatus can increase or decrease the high phase and/or low phase of the clock signal according to the settings in the mode registers.

At 606, the SoC/memory can check the adjusted clock duty cycle. At 608, if the duty cycle is correct or at the optimal value, the SoC/memory can stop the adjustment process; otherwise, the DCA apparatus repeat the above steps to perform further duty cycle adjustment. The SoC/memory controller may re-measure the clock signal after each adjustment to check whether or not the duty cycle is at the desired value (e.g., 50%).

In some aspects, the apparatus can sweep the clock duty cycle during initialization to ensure that the duty cycle of the clock signal is optimized for reliable operation (e.g., 50% duty cycle). For example, the apparatus can sweep a DCA to vary the clock duty cycle to find the optimal configuration for balancing the high and low phases of the clock signal. In some aspects, the SoC can use DCA sweeping to find the optimal operating point of the DCA (e.g., DCA 230 of FIG. 2) where the duty cycle is closest to the desired ratio (typically 50%) at the input of a clock divider (e.g., clock divider 212 of FIG. 2).

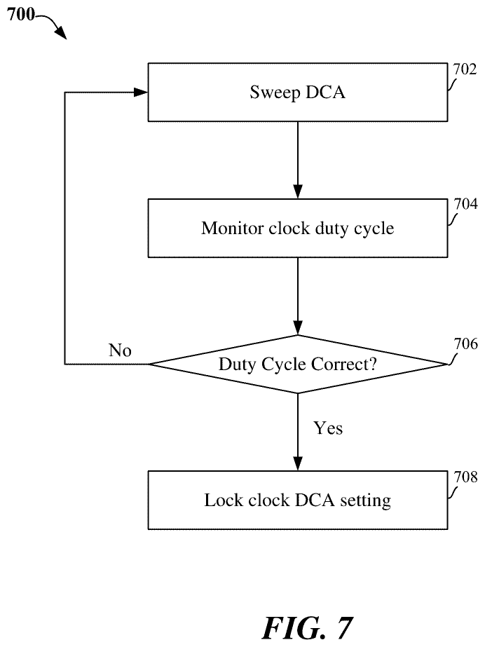

FIG. 7 illustrates an exemplary adjustment sweeping process 700 using a DCA according to some aspects of the disclosure. For example, the SoC 200 can use the adjustment process 700 to sweep the DCA 230 to determine the optimal operating point of the DCA based on a feedback from a DCM (e.g., DCM 232 of FIG. 2) such that the clock input to the clock divider is at the optimal duty cycle (e.g., 50% duty cycle).

At 702, the SoC can sweep the clock duty cycle of the DCA in a predetermined range. For example, the low end (LE) of the range is less than 50% and the high end (HE) of the range is greater than 50%. The SoC can iteratively modifying the DCA output clock signal to sweep over the entire range in predetermined steps or increments. At 704, the SoC can monitor the clock duty cycle using a DCM or equivalent circuitry at any desired location of the clock tree. In on example, the SoC can use the DCM 232 to measure the clock input duty cycle at the input of the clock divider 212 of FIG. 2. At 706, the SoC determines whether or not the clock duty cycle is sufficiently close (e.g., within 1%) to the desired value (e.g., 50%). The SoC can iteratively modifying the DCA until the desired duty cycle is achieved. At 708, the SoC can lock the DCA setting when the duty cycle is at the desire value, for example, at the input of the clock divider based on the feedback from the DCM.

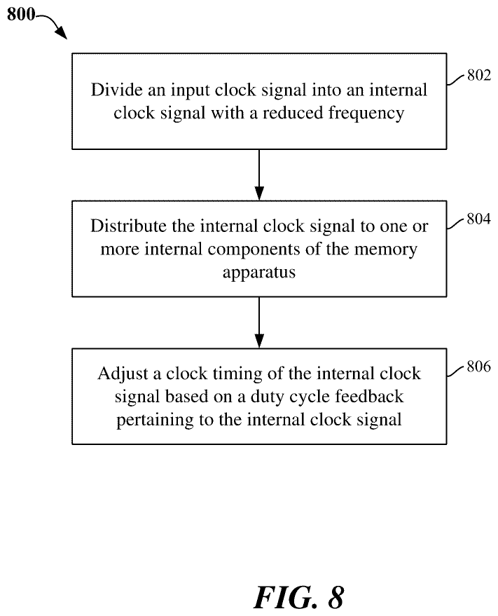

FIG. 8 is a flow chart illustrating a method 800 for adjusting the clock duty cycle of a memory apparatus according to some aspects of the disclosure. For example, the method 800 can be performed at a memory device (e.g., memory 202 of FIG. 2) to control a clock tree duty cycle as described above in relation to FIGS. 1-7 or any memory devices (e.g., LPDDR memory).

At 802, the memory apparatus can divide an input clock signal into an internal clock signal with a reduced frequency. In one aspect, the clock divider 212 can provide a means to divide the input clock signal (e.g., clock input at clock divider 212 of FIG. 2). The internal clock signal can be the clock signal of the clock tree 216 of FIG. 2. For example, the internal clock signal can have a frequency that is a fraction (e.g., ½, ¼, ⅛, etc.) of the frequency of the input clock signal after the clock divider.

At 804, the memory apparatus can distribute the internal clock signal to one or more internal components of the memory apparatus. In one aspect, the clock tree 216 of FIG. 2 can provide a means to distribute the internal clock signal to other components, for example, storage and I/O circuitry 218 of FIG. 2 that are downstream of a clock divider.

At 806, the memory apparatus can adjust a clock timing of the internal clock signal based on a duty cycle feedback pertaining to the internal clock signal. In one aspect, the duty cycle adjuster (DCA) 220 can provide a means to adjust the clock timing of the internal clock signal. For example, the DCA can adjust the duty cycle of the internal clock signal so that the internal clock signal is at or near the optimal duty cycle (e.g., 50%). In some aspects, the DCM 222 of FIG. 2 can provide a means to monitor the duty cycle of the internal clock signal, and send feedback to the DCA. For example, the DCA can adjust the high phase and/or the low phase of the internal clock signal to adjust its duty cycle to reach the optimal duty cycle.

In some aspects, the apparatus can include a first DCM (e.g., DCM 222 of FIG. 2) configured to monitor the internal clock signal generated by the clock divider. The first DCM can provide duty cycle feedback to a first DCA (e.g., DCA 220 of FIG. 2), enabling the first DCA to dynamically adjust the duty cycle of the internal clock signal based on real-time monitoring. This configuration ensures that the internal clock signal can maintain a precise duty cycle for optimal operation of the memory apparatus. In some aspects, the apparatus can include a second DCM (e.g., DCM 232 of FIG. 2) configured to monitor the input clock signal at the input of the clock divider (e.g., clock divider 212 of FIG. 2). The second DCM can provide feedback related to the clock timing of the input clock signal to a host (e.g., SoC 200 of FIG. 2) or a memory controller, enabling the SoC to make adjustments to the input clock source or timing to enhance synchronization with the memory apparatus. This monitoring and feedback mechanism improves overall system performance by ensuring that input clock signals meet timing requirements.

In some aspects, the first DCA can be configured to adjust the duty cycle of the internal clock signal generated by the clock divider without affecting the input clock signal. This independent adjustment capability ensures that changes to the internal clock signal do not introduce disruptions or instability to the input clock signal, thereby maintaining robust clock signal integrity within the memory apparatus.

In some aspects, the apparatus can include a second DCA (e.g., DCA 230 of FIG. 2) configured to adjust the clock timing of the input clock signal. The first DCA operates independently of the second DCA, enabling the memory apparatus to adjust the internal clock signal and input clock signal separately, without interference. This dual DCA configuration provides enhanced flexibility and precision in managing clock signals for high-speed memory operations. In some aspects, the apparatus can include a second DCM (e.g., DCM 232 of FIG. 2) configured to monitor the input clock signal and provide feedback pertaining to the clock timing of the input clock signal directly to the second DCA. This feedback loop enables the second DCA to dynamically adjust the input clock signal's timing based on real-time conditions, improving the stability and accuracy of the clock signal.

In some aspects, the apparatus can further include an input clock buffer (e.g., buffer 210 of FIG. 2) connected to the input of the clock divider, wherein the input clock buffer includes the second DCA. This integration of the second DCA within the input buffer provides a compact and efficient design for adjusting the input clock signal directly before it enters the clock divider, ensuring that the clock divider receives a properly adjusted signal.

In one configuration, the apparatuses described in FIGS. 1 and 2 include the various means for performing the processes and techniques described above in FIG. 8. For example, the aforementioned means may be the processor(s) 112 in which the invention resides shown in FIG. 1 configured to perform the functions recited by the aforementioned means. In another aspect, the aforementioned means may be a circuit or any apparatus configured to perform the functions recited by the aforementioned means.

Of course, in the above examples, the processor 112 is merely provided as an example, and other means for carrying out the described functions may be included within various aspects of the present disclosure, including but not limited to the instructions stored in a computer-readable storage medium (e.g., storage 118 of FIG. 1), or any other suitable apparatus or means described in any one of the FIGS. 1-8, and utilizing, for example, the processes and/or algorithms described herein in relation to FIGS. 1-9.

Some implementation examples are described in the following numbered clauses:
Aspect 1: A memory apparatus comprising: a clock divider configured to divide an input clock signal into an internal clock signal with a reduced frequency; a clock tree configured to distribute the internal clock signal to one or more internal components of the memory apparatus; and a first duty cycle adjuster (DCA) connected to the clock tree, the first DCA configured to adjust a clock timing of the internal clock signal based on a duty cycle feedback pertaining to the internal clock signal.
Aspect 2: The memory apparatus of aspect 1, further comprising a first duty cycle monitor (DCM) configured to: monitor the internal clock signal; and provide, to the first DCA, the duty cycle feedback pertaining to the monitored internal clock signal.
Aspect 3: The memory apparatus of aspect 2, further comprising a second DCM configured to: monitor the input clock signal at an input of the clock divider; and provide feedback pertaining to clock timing of the input clock signal to a system-on-chip (SoC).
Aspect 4: The memory apparatus of aspect 1, 2, or 3, wherein the first DCA is further configured to adjust a duty cycle of the internal clock signal without affecting the input clock signal.
Aspect 5: The memory apparatus of aspect 1, 2, or 3, further comprising a second DCA configured to adjust a clock timing of the input clock signal, the first DCA operated independent of the first DCA.
Aspect 6: The memory apparatus of aspect 5, further comprising a second DCM configured to: monitor the input clock signal; and provide feedback pertaining to clock timing of the input clock signal to the second DCA.
Aspect 7: The memory apparatus of aspect 5, further comprising: an input buffer connected to an input of the clock divider, the input buffer comprising the second DCA.
Aspect 8: A method for controlling clock timing of a memory apparatus, comprising: dividing an input clock signal into an internal clock signal with a reduced frequency; distributing the internal clock signal to one or more internal components of the memory apparatus; and adjusting a clock timing of the internal clock signal based on a duty cycle feedback pertaining to the internal clock signal.
Aspect 9: The method of aspect 8, further comprising: monitoring the internal clock signal using a first duty cycle monitor (DCM); and providing the duty cycle feedback pertaining to the monitored internal clock signal.
Aspect 10. The method of aspect 9, further comprising: monitoring the input clock signal at an input of a clock divider; and providing duty cycle feedback of the input clock signal to a system-on-chip (SoC).
Aspect 11: The method of aspect 10, further comprising: providing the duty cycle feedback of the input clock signal to a duty cycle adjuster (DCA) at the SoC.
Aspect 12: The method of aspect 9, 10, or 11, further comprising: providing the duty cycle feedback to a duty cycle adjuster (DCA) included in an input buffer of the memory apparatus.
Aspect 13: The method of aspect 8, 9, 10, or 11 further comprising: adjusting a duty cycle of the internal clock signal without affecting the input clock signal.
Aspect 14: The method of aspect claim 8, 9, 10, or 11 further comprising adjusting a clock timing of the input clock signal independent of the adjusting the clock timing of the internal clock signal.
Aspect 15: A memory apparatus, comprising: means for dividing an input clock signal into an internal clock signal with a reduced frequency; means for distributing the internal clock signal to one or more internal components of the memory apparatus; and means for adjusting a clock timing of the internal clock signal based on a duty cycle feedback pertaining to the internal clock signal.
Aspect 16: The memory apparatus of aspect 15, further comprising: means for monitoring the internal clock signal of a clock tree associated with a clock divider; and means for providing the duty cycle feedback pertaining to the internal clock signal to a first duty cycle adjuster (DCA) connected to an output of the clock divider.
Aspect 17: The memory apparatus of aspect 16, further comprising: means for monitoring the input clock signal at an input of the clock divider; and means for providing duty cycle feedback of the input clock signal to a system-on-chip (SoC).
Aspect 18: The memory apparatus of aspect 17, further comprising: means for providing the duty cycle feedback of the input clock signal to a second DCA at the SoC.
Aspect 19: The memory apparatus of aspect 17, further comprising: means for providing the duty cycle feedback to a second duty cycle adjuster included in an input buffer of the memory apparatus.
Aspect 20: The memory apparatus of aspect 15, 16, 17, 18, or 19, further comprising: means for adjusting a duty cycle of the internal clock signal without affecting the input clock signal.

It is understood that the specific order or hierarchy of steps in the processes disclosed is an illustration of exemplary approaches. Based upon design preferences, it is understood that the specific order or hierarchy of steps in the processes may be rearranged. Further, some steps may be combined or omitted. The accompanying method claims present elements of the various steps in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” Unless specifically stated otherwise, the term “some” refers to one or more. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.”

It is understood that the specific order or hierarchy of steps in the processes disclosed is an illustration of exemplary approaches. Based upon design preferences, it is understood that the specific order or hierarchy of steps in the processes may be rearranged. Further, some steps may be combined or omitted. The accompanying method claims present elements of the various steps in a sample order, and are not meant to be limited to the specific order or hierarchy presented.

What is claimed is:

1. A memory apparatus comprising:
a clock divider configured to divide an input clock signal into an internal clock signal with a reduced frequency;
a clock tree configured to distribute the internal clock signal to one or more internal components of the memory apparatus; and
a first duty cycle adjuster (DCA) connected to the clock tree, the first DCA configured to adjust a clock timing of the internal clock signal based on a duty cycle feedback pertaining to the internal clock signal.

2. The memory apparatus of claim 1, further comprising a first duty cycle monitor (DCM) configured to:
monitor the internal clock signal; and
provide, to the first DCA, the duty cycle feedback pertaining to the monitored internal clock signal.

3. The memory apparatus of claim 2, further comprising a second DCM configured to:
monitor the input clock signal at an input of the clock divider; and
provide feedback pertaining to clock timing of the input clock signal to a system-on-chip (SoC).

4. The memory apparatus of claim 1, wherein the first DCA is further configured to adjust a duty cycle of the internal clock signal without affecting the input clock signal.

5. The memory apparatus of claim 1, further comprising a second DCA configured to adjust a clock timing of the input clock signal, the first DCA operated independent of the first DCA.

6. The memory apparatus of claim 5, further comprising a second DCM configured to:
monitor the input clock signal; and
provide feedback pertaining to clock timing of the input clock signal to the second DCA.

7. The memory apparatus of claim 5, further comprising:
an input buffer connected to an input of the clock divider, the input buffer comprising the second DCA.

8. A method for controlling clock timing of a memory apparatus, comprising:
dividing an input clock signal into an internal clock signal with a reduced frequency;
distributing the internal clock signal to one or more internal components of the memory apparatus; and
adjusting a clock timing of the internal clock signal based on a duty cycle feedback pertaining to the internal clock signal.

9. The method of claim 8, further comprising:
monitoring the internal clock signal using a first duty cycle monitor (DCM); and
providing the duty cycle feedback pertaining to the monitored internal clock signal.

10. The method of claim 9, further comprising:
monitoring the input clock signal at an input of a clock divider; and
providing duty cycle feedback of the input clock signal to a system-on-chip (SoC).

11. The method of claim 10, further comprising:
providing the duty cycle feedback of the input clock signal to a duty cycle adjuster (DCA) at the SoC.

12. The method of claim 9, further comprising:
providing the duty cycle feedback to a duty cycle adjuster (DCA) included in an input buffer of the memory apparatus.

13. The method of claim 8, further comprising:
adjusting a duty cycle of the internal clock signal without affecting the input clock signal.

14. The method of claim 8, further comprising adjusting a clock timing of the input clock signal independent of the adjusting the clock timing of the internal clock signal.

15. A memory apparatus, comprising:
means for dividing an input clock signal into an internal clock signal with a reduced frequency;
means for distributing the internal clock signal to one or more internal components of the memory apparatus; and
means for adjusting a clock timing of the internal clock signal based on a duty cycle feedback pertaining to the internal clock signal.

16. The memory apparatus of claim 15, further comprising:
means for monitoring the internal clock signal of a clock tree associated with a clock divider; and
means for providing the duty cycle feedback pertaining to the internal clock signal to a first duty cycle adjuster (DCA) connected to an output of the clock divider.

17. The memory apparatus of claim 16, further comprising:
means for monitoring the input clock signal at an input of the clock divider; and
means for providing duty cycle feedback of the input clock signal to a system-on-chip (SoC).

18. The memory apparatus of claim 17, further comprising:
means for providing the duty cycle feedback of the input clock signal to a second DCA at the SoC.

19. The memory apparatus of claim 17, further comprising:
means for providing the duty cycle feedback to a second duty cycle adjuster included in an input buffer of the memory apparatus.

20. The memory apparatus of claim 15, further comprising:
means for adjusting a duty cycle of the internal clock signal without affecting the input clock signal.
